(19) United States
(12) Patent Application Publication
(10) Pub. No.: US 2015/0382465 A1
(43) Pub. Date: Dec. 31, 2015

(54) SYSTEMS AND METHODS FOR IMPLEMENTING DISPLAY DRIVERS

(71) Applicant: Pixtronix, Inc., San Diego, CA (US)

(72) Inventors: Jasper Lodewyk Steyn, Cupertino, CA (US); Stephen English, Billerica, MA (US)

(21) Appl. No.: 14/314,544

(22) Filed: Jun. 25, 2014

(51) Int. Cl. H05K 1/18; H05K 1/03; H05K 3/30; H05K 1/02

(52) U.S. Cl. CPC H05K 1/181; H05K 1/0274; H05K 1/0306; H05K 3/305; H05K 2201/068; H05K 2201/10166; H05K 2201/10128

(57) ABSTRACT

A device includes a first substrate formed of a first material and a plurality of electromechanical devices formed upon a surface of the first substrate. The device also includes an integrated circuit (IC) chip bonded to the surface of the first substrate where the integrated circuit chip is formed of a material selected from a group consisting of the first material or a material having a coefficient of thermal expansion (CTE) that is substantially similar to the CTE of the first material.

### TECHNICAL FIELD

This disclosure relates to the field of display devices, and more particularly, to driver elements for display devices.

### DESCRIPTION OF THE RELATED TECHNOLOGY

Existing flat panel displays are used in many commercial products such as high definition televisions (HDTV), cellular telephones, personal digital assistants (PDAs), camcorders, and laptop personal computers (PCs). It is desirable for displays to be lightweight, portable, rugged, and low-powered. Liquid-crystal based modulator displays are the most popular flat-panel display technology available today while MEMS-based light modulator displays are also available. Regardless of the type of modulator technology, flat panel displays rely on an active control matrix to control the display using thin-film transistors (TFTs).

A display typically includes of an array (or matrix) of picture elements (“pixels”). Thousands or millions of these pixels together create an image on the display. Thin-film transistors typically act as switches to individually turn each pixel “on” (light) or “off” (dark). The TFTs are the active elements, arranged in a control matrix, on a substrate of the display. The substrate, along with the control matrix, is often referred to as the display backplane.

A problem with displays is that the lowest cost display backplanes are typically based on a-Si or IGZO or other Metal Oxide TFT's. Alternatively, architectures using tunneling barrier devices have been proposed. Low Temperature Polysilicon (LTPS)-based display backplanes generally provide the best performance along with full CMOS capability, but at an increased cost. LTPS also enables the more convenient use of integrated row drivers for a display. For fast row driving on other display architectures, a dedicated driver IC (integrated circuit) chip form in silicon is usually required. Because silicon IC chips are relatively small, bonding such chips to glass substrates using “Chip on Glass” (COG) technology also requires a fan-out of their interconnect wires from the chip to connect to the rows of the array of pixels in a display. Unfortunately, this increases shelf or bezel area of the display and reduces the viewable display area.

### SUMMARY

The systems, methods and devices of this disclosure each have several innovative aspects, no single one of which is solely responsible for the desirable attributes disclosed herein.

In one aspect, a device includes a first substrate formed of a first material and a plurality of electromechanical devices formed upon a surface of the first substrate. The device also includes an integrated circuit (IC) chip bonded to the surface of the first substrate where the integrated circuit chip is formed of a material selected from a group consisting of the first material or a material having a coefficient of thermal expansion (CTE) that is substantially similar to the CTE of the first material.

In certain configurations, the first substrate is substantially transparent. The IC chip may be substantially transparent. The IC chip may include a glass-based IC chip. The first substrate may be formed of glass. The IC chip may include a low temperature polysilicon (LTPS) transistor. The first substrate may be a display backplane and the IC chip may be located substantially along a periphery of the display backplane. The IC chip may function as at least one of a gate driver and data driver.

In some configurations, the device may include a plurality of routing lines formed in the first substrate such that they extend away from the plurality of electromechanical devices. The IC chip may have a plurality of contact pads such that each of the routing lines extends towards and connects with a respective contact pad. Each of the routing lines may extend along a straight line from the electromechanical devices towards the integrated circuit chip. Each of the routing lines may connect to the integrated circuit chip at substantially a perpendicular angle with an edge of the integrated circuit chip. Each contact pad may be substantially aligned with at least one corresponding row and one corresponding column of pixels of a display. The plurality of electromechanical devices may extend along a first length while the IC chip has an edge of a second length. The edge of the IC chip may be arranged adjacent to and aligned with the first length of the electromechanical devices, such that the first length is substantially equal to second length.

In one configuration, the IC chip includes a second substrate. The IC chip may be bonded to the first substrate. The IC chip may be permanently bonded to the first substrate. In some implementations, at least one glass-based transistor on the IC chip is tested before bonding to the first substrate. The bonding may include at least one of anodic bonding, fusion, thermal compression bonding, anisotropic conductive film (ACF) bonding, or applying an adhesive between the first and second substrates. The adhesive may include, without limitation, an epoxy adhesive such as commonly used for sealing liquid crystal cells.

In certain configurations, the IC chip includes at least one LTPS transistor. The first substrate may include the display backplane of the display. In some implementations, the IC chip is located substantially along a periphery of the display backplane. The periphery of the display may include a non-viewable portion of the display.

In another aspect, a glass-based chip includes a first substrate that is connectable with a display backplane and a glass-based IC chip that is formed on the first substrate and arranged to drive at least one light modulator on the display backplane after the first substrate is connected to the display backplane. The glass-based IC chip may include a LTPS transistor. The process of connecting the glass-based chip to the display backplane may include bonding the glass-based chip to the display backplane. The bonding process may include any one or a combination of anodic bonding, fusion, thermal compression bonding, anisotropic conductive film (ACF) bonding, or applying an adhesive between the first and second substrates.

In one configuration, the glass-based chip includes multiple glass-based IC chips. The glass-based IC chip also includes at least one contact pad that is associated with each of the plurality of glass-based integrated circuits that connect with a corresponding routing line of a light modulator on the display backplane. Each contact pad may be substantially aligned with at least one corresponding row and one corresponding column of pixels on the display backplane.

In yet another aspect, a method for manufacturing a display includes: providing a first substrate formed of a first material, forming a plurality of electromechanical devices on the first substrate, providing an integrated circuit (IC) chip where the integrated circuit chip is formed of a material selected from a group consisting of the first material or a material having a coefficient of thermal expansion (CTE) that is substantially similar to the CTE of the first material, and then bonding the first substrate to the IC chip.

In some configurations, the method includes forming the IC chip by fabricating an active thin film circuit and a contact pad on a glass substrate. The first material may be glass. The method may further include forming a plurality of routing lines in the first substrate such that they extend away from the plurality of electromechanical devices. The IC chip may also have a plurality of contact pads such that the method includes extending each of the routing lines towards and connecting each of the routing lines with a respective contact pad. The method may include extending each of the routing lines along a straight line from the electromechanical devices towards the IC chip. The method may include connecting each of the routing lines to the IC chip at substantially a perpendicular angle with an edge of the IC chip. The method may further include aligning each contact pad substantially with at least one corresponding row and one corresponding column of pixels of a display.

In certain configurations, the method extends the plurality of electromechanical devices along a first length and the IC chip has an edge of a second length, such that the edge of the IC chip is adjacent to and aligned with the first length of the electromechanical devices, and the first length is substantially equal to second length. The method may include forming at least one glass-based transistor on the IC chip and testing the at least one glass-based transistor before bonding the IC chip to the first substrate

The bonding process may include any one or combination of anodic bonding, fusion, thermal compression bonding, anisotropic conductive film (ACF) bonding, or applying an adhesive between the first substrate and IC chip. The method may also include forming a plurality of glass-based transistors on the IC chip where each glass based transistor includes at least one drive connector. The method may further include aligning each of the at least one drive connector with a corresponding routing line of a light modulator on the first substrate. The IC chip may be bonded to a periphery of the first substrate.

Details of one or more implementations of the subject matter described in this disclosure are set forth in the accompanying drawings and the description below. Although the examples provided in this disclosure are primarily described in terms of EMS and MEMS-based displays the concepts provided herein may apply to other types of displays such as liquid crystal displays (LCDs), organic light-emitting diode (“OLED”) displays, and field emission displays. Other features, aspects, and advantages will become apparent from the description, the drawings and the claims. Note that the relative dimensions of the following figures may not be drawn to scale.

### BRIEF DESCRIPTION OF THE DRAWINGS

The foregoing discussion will be understood more readily from the following detailed description with reference to the following drawings

FIG. 1A is an isometric view of an example display apparatus;

FIG. 1B is a block diagram of the display apparatus of FIG. 1A;

FIG. 2 is a perspective view of an illustrative shutter-based light modulator suitable for incorporation into the MEMS-based display of FIG. 1A;

FIG. 3A is a schematic diagram of a control matrix suitable for controlling the light modulators incorporated into the MEMS-based display of FIG. 1A;

FIG. 3B is a perspective view of an array of shutter-based light modulators connected to the control matrix of FIG. 3A;

FIGS. 4A and 4B are plan views of a dual-actuated shutter assembly in the open and closed states respectively;

FIG. 5 is a cross-sectional view of a shutter-based display apparatus;

FIG. 6 is a diagram of a prior art display illustrating the connector fan out from silicon-based drivers;

FIG. 7 is a diagram of a display including glass-based driver chips;

FIG. 8 is a side view of a display illustrating a glass-based IC chip bonded to a display backplane or substrate;

FIG. 9 is another diagram of a display illustrating the alignment of the connectors on glass-based chips with the rows and columns of a light modulator array;

FIG. 10 is a flow diagram of a process for manufacturing a display including glass-based driver integrated circuits; and

FIGS. 11A and 11B are system block diagrams illustrating a display device that includes a plurality of light modulator display elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in any device, apparatus, or system that can be configured to display an image, whether in motion (such as video) or stationary (such as still images), and whether textual, graphical or pictorial. More particularly, it is contemplated that the described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, global positioning system (GPS) receivers/navigators, cameras, digital media players (such as MP3 players), camcorders, game consoles, wrist watches, clocks, calculators, television monitors, flat panel displays, electronic reading devices (e.g., e-readers), computer monitors, auto displays (including odometer and speedometer displays, etc.), cockpit controls or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS) applications including microelectromechanical systems (MEMS) applications, as well as non-EMS applications), aesthetic structures (such as display of images on a piece of jewelry or clothing) and a variety of EMS devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Thus, the teachings are not intended to be limited to the implementations depicted solely in the Figures, but instead have wide applicability as will be readily apparent to one having ordinary skill in the art.

To provide an overall understanding of the application, certain illustrative implementations will now be described. This application proposes fabricating a display using a low cost display backplane combined with integrated circuits (ICs) chips formed from glass substrates. Glass-based IC chips may be combined with, bonded to, or attached to a separate glass substrate that contains, e.g., a display backplane. In some implementations, the glass-based IC chips are driver chips that include high mobility LTPS transistors.

Because the ICs are arranged or formed on glass, instead of silicon, there is little to no coefficient of thermal expansion (CTE) mismatch between the glass-based IC chips and the glass display backplane as opposed to the mismatch experienced when using COG technology which bonds silicon chips to glass substrates where such a CTE mismatch can result in damage to the silicon chips or failure of the bond between the silicon and glass, ultimately, resulting in failure of a display. With glass-based IC chips, the contact or bond pads may be large to relax the alignment tolerance with the rows or columns of an array of light modulators on the display. Furthermore, a relatively large glass-based chip, as compared to a silicon chip, requires substantially less fan-out. Therefore, a glass-based chip is able to maintain a slimmer border on the display backplane as opposed to the wider border required for silicon IC chip fan-out. Hence, one advantage of the slimmer border profile is that a larger portion of the display backplane can be used as the viewable display area.

Another advantage of using glass-based IC chips is that the glass-based IC chips can be formed on a glass substrate separately from the display backplane and then bonded to the edges of the display backplane. Such a process enables the glass-based IC chips to be tested for proper operation prior to their addition to the backplane. This reduces the overall cost of manufacturing displays by requiring only replacement of faulty glass-based chips instead of the whole display. Also, by forming a glass-based chip on a separate substrate (e.g., glass), the relatively more expensive LTPS process can be limited to the glass-based driver chip, while less expensive TFT technologies (e.g., A-Si, IGZO, or tunneling barrier devices) are used as switches for the pixels in the display area.

While the following detailed description includes examples of electromechanical devices, transistors, and drivers employed within displays, it will be understood by one having ordinary skill in the art that the systems and methods described herein may be adapted and modified as is appropriate for the application being addressed and that the systems and methods described herein may be employed in other suitable applications, and that such other additions and modifications will not depart from the scope hereof.

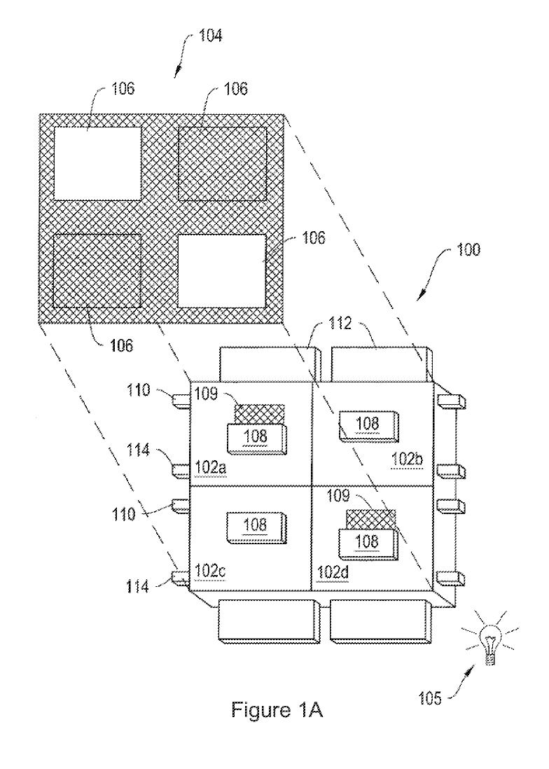

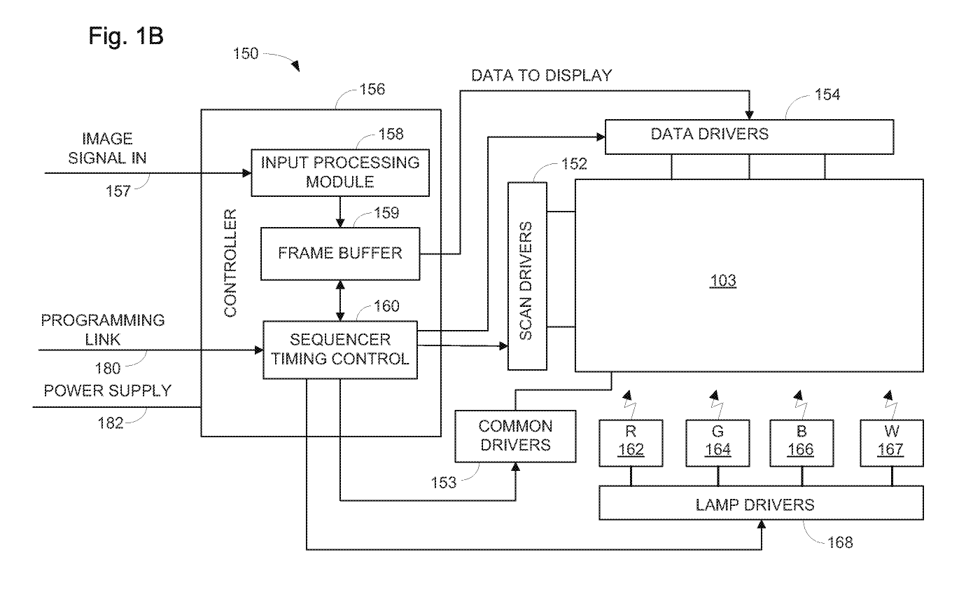

FIG. 1A is a schematic diagram of a direct-view MEMS-based display apparatus 100. The display apparatus 100 includes a plurality of light modulators 102a-102d (generally “light modulators 102”) arranged in rows and columns. In the display apparatus 100, light modulators 102a and 102d are in the open state, allowing light to pass. Light modulators 102b and 102c are in the closed state, obstructing the passage of light. By selectively setting the states of the light modulators 102a-102d, the display apparatus 100 can be utilized to form an image 104 for a backlit display, if illuminated by a lamp or lamps 105. In another implementation, the apparatus 100 may form an image by reflection of ambient light originating from the front of the apparatus. In another implementation, the apparatus 100 may form an image by reflection of light from a lamp or lamps positioned in the front of the display, i.e. by use of a front light. In one of the closed or open states, the light modulators 102 interfere with light in an optical path by, for example, and without limitation, blocking, reflecting, absorbing, filtering, polarizing, diffracting, or otherwise altering a property or path of the light.

In the display apparatus 100, each light modulator 102 corresponds to a pixel 106 in the image 104. In other implementations, the display apparatus 100 may utilize a plurality of light modulators to form a pixel 106 in the image 104. For example, the display apparatus 100 may include three color-specific light modulators 102. By selectively opening one or more of the color-specific light modulators 102 corresponding to a particular pixel 106, the display apparatus 100 can generate a color pixel 106 in the image 104. In another example, the display apparatus 100 includes two or more light modulators 102 per pixel 106 to provide grayscale in an image 104. With respect to an image, a “pixel” corresponds to the smallest picture element defined by the resolution of the image. With respect to structural components of the display apparatus 100, the term “pixel” refers to the combined mechanical and electrical components utilized to modulate the light that forms a single pixel of the image.

Display apparatus 100 is a direct-view display in that it does not require imaging optics. The user sees an image by looking directly at the display apparatus 100. In alternate implementations, the display apparatus 100 is incorporated into a projection display. In such implementations, the display forms an image by projecting light onto a screen or onto a wall. In projection applications, the display apparatus 100 is substantially smaller than the projected image 104.

Direct-view displays may operate in either a transmissive or reflective mode. In a transmissive display, the light modulators filter or selectively block light which originates from a lamp or lamps positioned behind the display. The light from the lamps is optionally injected into a light guide or “backlight”. Transmissive direct-view display implementations are often built onto transparent or glass substrates to facilitate a sandwich assembly arrangement where one substrate, containing the light modulators, is positioned directly on top of the backlight. In some transmissive display implementations, a color-specific light modulator is created by associating a color filter material with each modulator 102. In other transmissive display implementations, colors can be generated, as described below, using a field sequential color method by alternating illumination of lamps with different primary colors.

Each light modulator 102 includes a shutter 108 and an aperture 109. To illuminate a pixel 106 in the image 104, the shutter 108 is positioned such that it allows light to pass through the aperture 109 towards a viewer. To keep a pixel 106 unlit, the shutter 108 is positioned such that it obstructs the passage of light through the aperture 109. The aperture 109 is defined by an opening patterned through a reflective or light-absorbing material.

The display apparatus also includes a control matrix connected to the substrate and to the light modulators for controlling the movement of the shutters. The control matrix includes a series of electrical interconnects (e.g., interconnects 110, 112, and 114), including at least one write-enable interconnect 110 (also referred to as a “scan-line interconnect”) per row of pixels, one data interconnect 112 for each column of pixels, and one common interconnect 114 providing a common voltage to all pixels, or at least to pixels from both multiple columns and multiples rows in the display apparatus 100. In response to the application of an appropriate voltage (the “write-enabling voltage, V_{we}”), the write-enable interconnect 110 for a given row of pixels prepares the pixels in the row to accept new shutter movement instructions. The data interconnects 112 communicate the new movement instructions in the form of data voltage pulses. The data voltage pulses applied to the data interconnects 112, in some implementations, directly contribute to an electrostatic movement of the shutters. In other implementations, the data voltage pulses control switches, e.g., transistors or other non-linear circuit elements that control the application of separate actuation voltages, which are typically higher in magnitude than the data voltages, to the light modulators 102. The application of these actuation voltages then results in the electrostatic driven movement of the shutters 108.

FIG. 1B is a block diagram 150 of the display apparatus 100. Referring to FIGS. 1A and 1B, in addition to the elements of the display apparatus 100 described above, as depicted in the block diagram 150, the display apparatus 100 includes a plurality of scan drivers 152 (also referred to as “write enabling voltage sources”) and a plurality of data drivers 154 (also referred to as “data voltage sources”). The scan drivers 152 apply write enabling voltages to scan-line interconnects 110. The data drivers 154 apply data voltages to the data interconnects 112. In some implementations of the display apparatus, the data drivers 154 are configured to provide analog data voltages to the light modulators, especially where the gray scale of the image 104 is to be derived in analog fashion. In analog operation the light modulators 102 are designed such that when a range of intermediate voltages is applied through the data interconnects 112 there results a range of intermediate open states in the shutters 108 and therefore a range of intermediate illumination states or gray scales in the image 104.

In other cases the data drivers 154 are configured to apply only a reduced set of 2, 3, or 4 digital voltage levels to the control matrix. These voltage levels are designed to set, in digital fashion, either an open state or a closed state to each of the shutters 108.

The scan drivers 152 and the data drivers 154 are connected to digital controller circuit 156 (also referred to as the “controller 156”). The controller 156 includes an input processing module 158, which processes an incoming image signal 157 into a digital image format appropriate to the spatial addressing and the gray scale capabilities of the display 100. The pixel location and gray scale data of each image is stored in a frame buffer 159 so that the data can be fed out as needed to the data drivers 154. The data is sent to the data drivers 154 in mostly serial fashion, organized in predetermined sequences grouped by rows and by image frames. The data drivers 154 can include series to parallel data converters, level shifting, and for some applications digital to analog voltage converters.

The display 100 apparatus optionally includes a set of common drivers 153, also referred to as common voltage sources. In some implementations the common drivers 153 provide a DC common potential to all light modulators within the array of light modulators 103, for instance by supplying voltage to a series of common interconnects 114. In other implementations the common drivers 153, following commands from the controller 156, issue voltage pulses or signals to the array of light modulators 103, for instance global actuation pulses which are capable of driving or initiating simultaneous actuation of all light modulators in multiple rows and columns of the array 103.

All of the drivers (e.g., scan drivers 152, data drivers 154, and common drivers 153) for different display functions are time-synchronized by a timing-control module 160 in the controller 156. Timing commands from the module 160 coordinate the illumination of red, green and blue and white lamps (162, 164, 166, and 167 respectively) via lamp drivers 168, the write-enabling and sequencing of specific rows within the array of pixels 103, the output of voltages from the data drivers 154, and the output of voltages that provide for light modulator actuation.

The controller 156 determines the sequencing or addressing scheme by which each of the shutters 108 in the array 103 can be re-set to the illumination levels appropriate to a new image 104. New images 104 can be set at periodic intervals. For instance, for video displays, the color images 104 or frames of video are refreshed at frequencies ranging from 10 to 300 Hertz. In some implementations, the setting of an image frame to the array 103 is synchronized with the illumination of the lamps 162, 164, and 166 such that alternate image frames are illuminated with an alternating series of colors, such as red, green, and blue. The image frames for each respective color is referred to as a color sub-frame. In this method, referred to as the field sequential color method, if the color sub-frames are alternated at frequencies in excess of 20 Hz, the human brain will average the alternating frame images into the perception of an image having a broad and continuous range of colors. In alternate implementations, four or more lamps with primary colors can be employed in display apparatus 100, employing primaries other than red, green, and blue.

In some implementations, where the display apparatus 100 is designed for the digital switching of shutters 108 between open and closed states, the controller 156 determines the addressing sequence and the time intervals between image frames to produce images 104 with appropriate gray scale. The process of generating varying levels of grayscale by controlling the amount of time a shutter 108 is open in a particular frame is referred to as time division gray scale. In some implementations of time division gray scale, the controller 156 determines the time period or the fraction of time within each frame that a shutter 108 is allowed to remain in the open state, according to the illumination level or gray scale desired of that pixel. In other implementations, for each image frame, the controller 156 sets a plurality of sub-frame images in multiple rows and columns of the array 103, and the controller alters the duration over which each sub-frame image is illuminated in proportion to a gray scale value or significance value employed within a coded word for gray scale. For instance, the illumination times for a series of sub-frame images can be varied in proportion to the binary coding series 1,2,4,8 . . . . The shutters 108 for each pixel in the array 103 are then set to either the open or closed state within a sub-frame image according to the value at a corresponding position within the pixel's binary coded word for gray level.

In other implementations, the controller alters the intensity of light from the lamps 162, 164, and 166 in proportion to the gray scale value desired for a particular sub-frame image. A number of hybrid techniques are also available for forming colors and gray scale from an array of shutters 108. For instance, the time division techniques described above can be combined with the use of multiple shutters 108 per pixel, or the gray scale value for a particular sub-frame image can be established through a combination of both sub-frame timing and lamp intensity.

In some implementations, the data for an image state 104 is loaded by the controller 156 to the modulator array 103 by a sequential addressing of individual rows, also referred to as scan lines. For each row or scan line in the sequence, the scan driver 152 applies a write-enable voltage to the write enable interconnect 110 for that row of the array 103, and subsequently the data driver 154 supplies data voltages, corresponding to desired shutter states, for each column in the selected row. This process repeats until data has been loaded for all rows in the array. In some implementations the sequence of selected rows for data loading is linear, proceeding from top to bottom in the array. In other implementations, the sequence of selected rows is pseudo-randomized, in order to minimize visual artifacts. In further implementations, the sequencing is organized by blocks, where, for a block, the data for only a certain fraction of the image state 104 is loaded to the array, for instance by addressing only every 5^{th} row of the array in sequence.

In some implementations, the process for loading image data to the array 103 is separated in time from the process of actuating the shutters 108. In these implementations, the modulator array 103 may include data memory elements for each pixel in the array 103 and the control matrix may include a global actuation interconnect for carrying trigger signals, from common driver 153, to initiate simultaneous actuation of shutters 108 according to data stored in the memory elements. Various addressing sequences, many of which are described in U.S. patent application Ser. No. 11/643,042, can be coordinated by means of the timing control module 160.

In alternative implementations, the array of pixels 103 and the control matrix that controls the pixels may be arranged in configurations other than rectangular rows and columns. For example, the pixels can be arranged in hexagonal arrays or curvilinear rows and columns. In general, as used herein, the term scan-line shall refer to any plurality of pixels that share a write-enabling interconnect.

The display 100 includes of a plurality of functional blocks including the timing control module 160, the frame buffer 159, scan drivers 152, data drivers 154, and drivers 153 and 168. Each block can be understood to represent either a distinguishable hardware circuit or a module of executable code. In some implementations, the functional blocks are provided as distinct chips or circuits connected together by means of circuit boards or cables. Alternately, many of these circuits can be fabricated along with the pixel array 103 on the same substrate of glass or plastic. In other implementations, multiple circuits, drivers, processors, or control functions from block diagram 150 may be integrated together within a single silicon chip, which is then bonded directly to the transparent substrate holding pixel array 103.

The controller 156 includes a programming link 180 by which the addressing, color, or gray scale algorithms, which are implemented within controller 156, can be altered according to the needs of particular applications. In some implementations, the programming link 180 conveys information from environmental sensors, such as ambient light or temperature sensors, so that the controller 156 can adjust imaging modes or backlight power in correspondence with environmental conditions. The controller 156 also includes a power supply input 182 which provides the power needed for lamps as well as light modulator actuation. Where necessary, the drivers 152, 153, 154, and 168 may include or be associated with DC-DC converters for transforming an input voltage at 182 into various voltages sufficient for the actuation of shutters 108 or illumination of the lamps, such as lamps 162, 164, 166, and 167.

MEMS Light Modulators

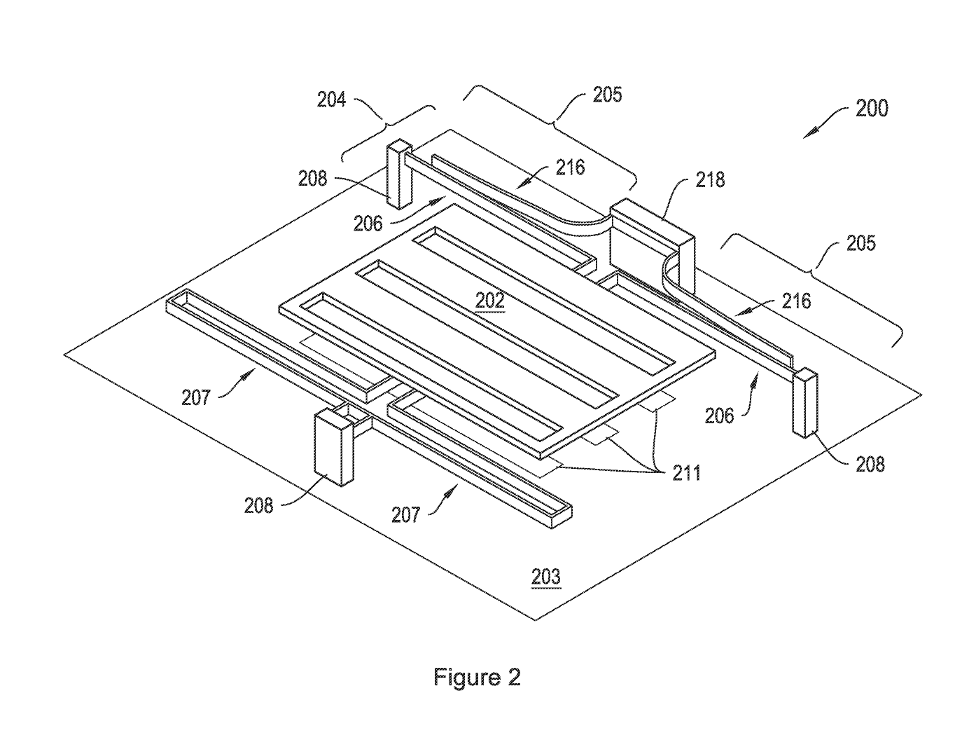

FIG. 2 is a perspective view of an illustrative shutter-based light modulator 200 suitable for incorporation into the MEMS-based display apparatus 100 of FIG. 1A. The shutter-based light modulator 200 (also referred to as shutter assembly 200) includes a shutter 202 coupled to an actuator 204. The actuator 204 is formed from two separate compliant electrode beam actuators 205 (the “actuators 205”) The shutter 202 couples on one side to the actuators 205. The actuators 205 move the shutter 202 transversely over a surface 203 in a plane of motion which is substantially parallel to the surface 203. The opposite side of the shutter 202 couples to a spring 207 which provides a restoring force opposing the forces exerted by the actuator 204.

Each actuator 205 includes a compliant load beam 206 connecting the shutter 202 to a load anchor 208. The load anchors 208 along with the compliant load beams 206 serve as mechanical supports, keeping the shutter 202 suspended proximate to the surface 203. The load anchors 208 physically connect the compliant load beams 206 and the shutter 202 to the surface 203 and electrically connect the load beams 206 to a bias voltage, in some instances, ground.

Each actuator 205 also includes a compliant drive beam 216 positioned adjacent to each load beam 206. The drive beams 216 couple at one end to a drive beam anchor 218 shared between the drive beams 216. The other end of each drive beam 216 is free to move. Each drive beam 216 is curved such that it is closest to the load beam 206 near the free end of the drive beam 216 and the anchored end of the load beam 206.

The surface 203 includes one or more apertures 211 for admitting the passage of light. If the shutter assembly 200 is formed on an opaque substrate, made for example from silicon, then the surface 203 is a surface of the substrate, and the apertures 211 are formed by etching an array of holes through the substrate. If the shutter assembly 200 is formed on a transparent substrate, made for example of glass or plastic, then the surface 203 is a surface of a light blocking layer deposited on the substrate, and the apertures are formed by etching the surface 203 into an array of holes 211. The apertures 211 can be generally circular, elliptical, polygonal, serpentine, or irregular in shape.

In operation, a display apparatus incorporating the light modulator 200 applies an electric potential to the drive beams 216 via the drive beam anchor 218. A second electric potential may be applied to the load beams 206. The resulting potential difference between the drive beams 216 and the load beams 206 pulls the free ends of the drive beams 216 towards the anchored ends of the load beams 206, and pulls the shutter ends of the load beams 206 toward the anchored ends of the drive beams 216, thereby driving the shutter 202 transversely towards the drive anchor 218. The compliant members 206 act as springs, such that when the voltage across the beams 206 and 216 is removed, the load beams 206 push the shutter 202 back into its initial position, releasing the stress stored in the load beams 206.

The shutter assembly 200, also referred to as an elastic shutter assembly, incorporates a passive restoring force, such as a spring, for returning a shutter to its rest or relaxed position after voltages have been removed. A number of elastic restore mechanisms and various electrostatic couplings can be designed into or in conjunction with electrostatic actuators, the compliant beams illustrated in shutter assembly 200 being just one example. For instance, a highly non-linear voltage-displacement response can be provided which favors an abrupt transition between “open” vs. “closed” states of operation, and which, in many cases, provides a bi-stable or hysteretic operating characteristic for the shutter assembly. Other electrostatic actuators can be designed with more incremental voltage-displacement responses and with considerably reduced hysteresis, as may be used for analog gray scale operation.

The actuator 205 within the elastic shutter assembly is said to operate between a closed or actuated position and a relaxed position. The designer, however, can choose to place apertures 211 such that shutter assembly 200 is in either the “open” state, i.e. passing light, or in the “closed” state, i.e. blocking light, whenever actuator 205 is in its relaxed position. For illustrative purposes, it is assumed below that elastic shutter assemblies described herein are designed to be open in their relaxed state.

In many cases, a dual set of “open” and “closed” actuators may be provided as part of a shutter assembly so that the control electronics are capable of electrostatically driving the shutters into each of the open and closed states.

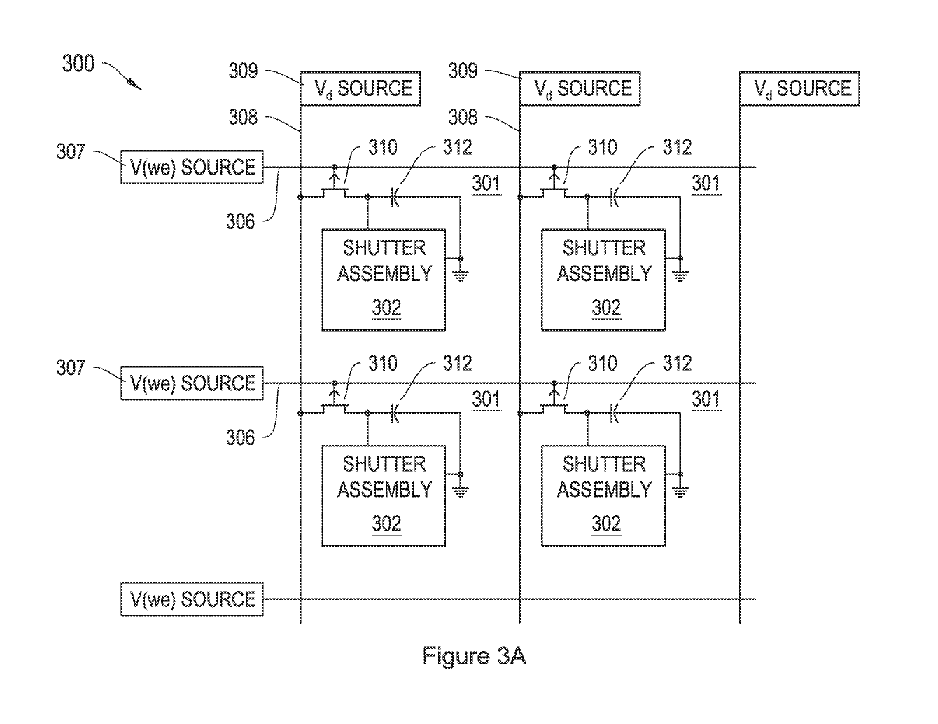

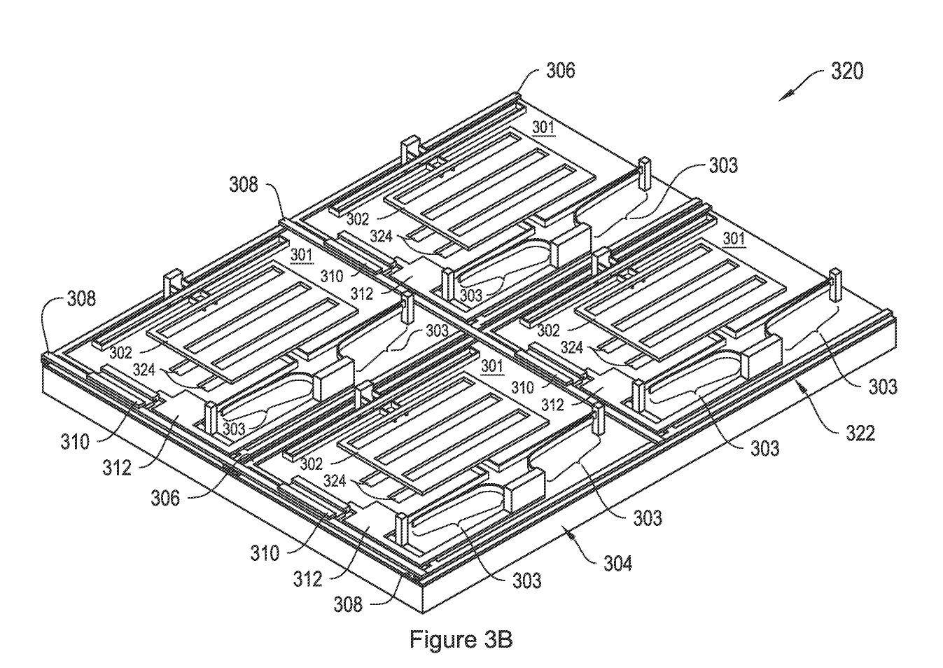

FIG. 3A is a schematic diagram of a control matrix 300 suitable for controlling the light modulators incorporated into the MEMS-based display apparatus 100 of FIG. 1A. FIG. 3B is a perspective view of an array 320 of shutter-based light modulators connected to the control matrix 300 of FIG. 3A. The control matrix 300 may address an array of pixels 320 (the “array 320”). Each pixel 301 includes an elastic shutter assembly 302, such as the shutter assembly 200 of FIG. 2A, controlled by an actuator 303. Each pixel also includes an aperture layer 322 that includes apertures 324.

The control matrix 300 may be fabricated as a diffused or thin-film-deposited electrical circuit on the surface of a substrate 304 on which the shutter assemblies 302 are formed. The control matrix 300 may include a scan-line interconnect 306 for each row of pixels 301 in the control matrix 300 and a data-interconnect 308 for each column of pixels 301 in the control matrix 300. Each scan-line interconnect 306 electrically connects a write-enabling voltage source 307 to the pixels 301 in a corresponding row of pixels 301. Each data interconnect 308 electrically connects a data voltage source, (“Vd source”) 309 to the pixels 301 in a corresponding column of pixels 301. In control matrix 300, the data voltage V_{d} provides the majority of the energy necessary for actuation of the shutter assemblies 302. Thus, the data voltage source 309 also serves as an actuation voltage source.

FIG. 3B is a perspective view of an array of shutter-based light modulators connected to the control matrix of FIG. 3A. Referring to FIGS. 3A and 3B, for each pixel 301 or for each shutter assembly 302 in the array of pixels 320, the control matrix 300 includes a transistor 310 and a capacitor 312. The gate of each transistor 310 is electrically connected to the scan-line interconnect 306 of the row in the array 320 in which the pixel 301 is located. The source of each transistor 310 is electrically connected to its corresponding data interconnect 308. The actuators 303 of each shutter assembly 302 include two electrodes. The drain of each transistor 310 is electrically connected in parallel to one electrode of the corresponding capacitor 312 and to one of the electrodes of the corresponding actuator 303. The other electrode of the capacitor 312 and the other electrode of the actuator 303 in shutter assembly 302 are connected to a common or ground potential. In alternate implementations, the transistors 310 can be replaced with semiconductor diodes and or metal-insulator-metal sandwich type switching elements.

In operation, to form an image, the control matrix 300 write-enables each row in the array 320 in a sequence by applying V_{we} to each scan-line interconnect 306 in turn. For a write-enabled row, the application of V_{we} to the gates of the transistors 310 of the pixels 301 in the row allows the flow of current through the data interconnects 308 through the transistors 310 to apply a potential to the actuator 303 of the shutter assembly 302. While the row is write-enabled, data voltages V_{d} are selectively applied to the data interconnects 308. In implementations providing analog gray scale, the data voltage applied to each data interconnect 308 is varied in relation to the desired brightness of the pixel 301 located at the intersection of the write-enabled scan-line interconnect 306 and the data interconnect 308.

In implementations providing digital control schemes, the data voltage is selected to be either a relatively low magnitude voltage (i.e., a voltage near ground) or to meet or exceed Vₐₜ (the actuation threshold voltage). In response to the application of Vₐₜ to a data interconnect 308, the actuator 303 in the corresponding shutter assembly 302 actuates, opening the shutter in that shutter assembly 302. The voltage applied to the data interconnect 308 remains stored in the capacitor 312 of the pixel 301 even after the control matrix 300 ceases to apply V_{we} to a row. It is not necessary, therefore, to wait and hold the voltage V_{we} on a row for times long enough for the shutter assembly 302 to actuate; such actuation can proceed after the write-enabling voltage has been removed from the row. The capacitors 312 also function as memory elements within the array 320, storing actuation instructions for periods as long as is necessary for the illumination of an image frame.

The pixels 301 as well as the control matrix 300 of the array 320 are formed on a substrate 304. The array includes an aperture layer 322, disposed on the substrate 304, which includes a set of apertures 324 for respective pixels 301 in the array 320. The apertures 324 are aligned with the shutter assemblies 302 in each pixel. In one implementation the substrate 304 is made of a transparent material, such as glass or plastic. In another implementation the substrate 304 is made of an opaque material, but in which holes are etched to form the apertures 324.

Components of shutter assemblies 302 are processed either at the same time as the control matrix 300 or in subsequent processing steps on the same substrate. The electrical components in control matrix 300 are fabricated using many thin film techniques in common with the manufacture of thin film transistor arrays for liquid crystal displays. Available techniques are described in Den Boer, Active Matrix Liquid Crystal Displays (Elsevier, Amsterdam, 2005), the entirety of which is incorporated herein by reference. The shutter assemblies are fabricated using techniques similar to the art of micromachining or from the manufacture of micromechanical (i.e., MEMS) devices. Many applicable thin film MEMS techniques are described in Rai-Choudhury, ed., Handbook of Microlithography, Micromachining & Microfabrication (SPIE Optical Engineering Press, Bellingham, Wash. 1997), the entirety of which is incorporated herein by reference. For instance, the shutter assembly 302 can be formed from thin films of amorphous silicon, deposited by a chemical vapor deposition process.

The shutter assembly 302 together with the actuator 303 can be made bi-stable. That is, the shutters can exist in at least two equilibrium positions (e.g. open or closed) with little or no power required to hold them in either position. More particularly, the shutter assembly 302 can be mechanically bi-stable. Once the shutter of the shutter assembly 302 is set in position, no electrical energy or holding voltage is required to maintain that position. The mechanical stresses on the physical elements of the shutter assembly 302 can hold the shutter in place.

The shutter assembly 302 together with the actuator 303 can also be made electrically bi-stable. In an electrically bi-stable shutter assembly, there exists a range of voltages below the actuation voltage of the shutter assembly, which if applied to a closed actuator (with the shutter being either open or closed), holds the actuator closed and the shutter in position, even if an opposing force is exerted on the shutter. The opposing force may be exerted by a spring such as spring 207 in shutter-based light modulator 200, or the opposing force may be exerted by an opposing actuator, such as an “open” or “closed” actuator.

The light modulator array 320 is depicted as having a single MEMS light modulator per pixel. Other implementations are possible in which multiple MEMS light modulators are provided in each pixel, thereby providing the possibility of more than just binary “on” or “off” optical states in each pixel. Certain forms of coded area division gray scale are possible where multiple MEMS light modulators in the pixel are provided, and where apertures 324, which are associated with each of the light modulators, have unequal areas.

In other implementations, the roller-based light modulator 220, the light tap 250, or the electrowetting-based light modulation array 270, as well as other MEMS-based light modulators, can be substituted for the shutter assembly 302 within the light modulator array 320.

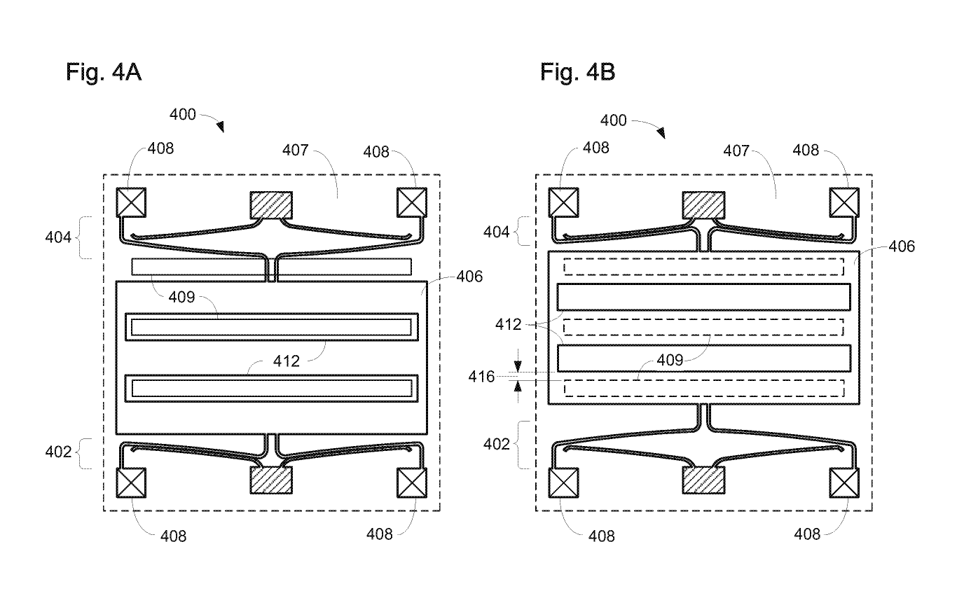

FIGS. 4A and 4B illustrate an alternative shutter-based light modulator (shutter assembly) 400 suitable for inclusion in various implementations. The light modulator 400 is an example of a dual actuator shutter assembly, and is shown in FIG. 4A in an open state. FIG. 4B is a view of the dual actuator shutter assembly 400 in a closed state. In contrast to the shutter assembly 200, shutter assembly 400 includes actuators 402 and 404 on either side of a shutter 406. Each actuator 402 and 404 is independently controlled. A first actuator, a shutter-open actuator 402, serves to open the shutter 406. A second opposing actuator, the shutter-close actuator 404, serves to close the shutter 406. Both actuators 402 and 404 are compliant beam electrode actuators. The actuators 402 and 404 open and close the shutter 406 by driving the shutter 406 substantially in a plane parallel to an aperture layer 407 over which the shutter is suspended. The shutter 406 is suspended a short distance over the aperture layer 407 by anchors 408 attached to the actuators 402 and 404. The inclusion of supports attached to both ends of the shutter 406 along its axis of a direction of motion reduces out of plane motion of the shutter 406 and confines the motion substantially to a plane parallel to the substrate. By analogy to the control matrix 300 of FIG. 3A, a control matrix suitable for use with shutter assembly 400 might include one transistor and one capacitor for each of the opposing shutter-open and shutter-close actuators 402 and 404.

The shutter 406 includes two shutter apertures 412 through which light can pass. The aperture layer 407 includes a set of three apertures 409. In FIG. 4A, the shutter assembly 400 is in the open state and, as such, the shutter-open actuator 402 has been actuated, the shutter-close actuator 404 is in its relaxed position, and the centerlines of apertures 412 and 409 coincide. In FIG. 4B the shutter assembly 400 has been moved to the closed state and, as such, the shutter-open actuator 402 is in its relaxed position, the shutter-close actuator 404 has been actuated, and the light blocking portions of shutter 406 are now in position to block transmission of light through the apertures 409 (shown as dotted lines).

Each aperture has at least one edge around its periphery. For example, the rectangular apertures 409 have four edges. In alternative implementations in which circular, elliptical, oval, or other curved apertures are formed in the aperture layer 407, each aperture may have only a single edge. In other implementations the apertures need not be separated or disjoint in the mathematical sense, but instead can be connected. That is to say, while portions or shaped sections of the aperture may maintain a correspondence to each shutter, several of these sections may be connected such that a single continuous perimeter of the aperture is shared by multiple shutters.

In order to allow light with a variety of exit angles to pass through apertures 412 and 409 in the open state, it is advantageous to provide a width or size for shutter apertures 412 which is larger than a corresponding width or size of apertures 409 in the aperture layer 407. In order to effectively block light from escaping in the closed state, the light blocking portions of the shutter 406 may be arranged to overlap the apertures 409. FIG. 4B shows a predefined overlap 416 between the edge of light blocking portions in the shutter 406 and one edge of the aperture 409 formed in aperture layer 407.

The electrostatic actuators 402 and 404 are designed so that their voltage—displacement behavior provides a bi-stable characteristic to the shutter assembly 400. For each of the shutter-open and shutter-close actuators there exists a range of voltages below the actuation voltage, which if applied while that actuator is in the closed state (with the shutter being either open or closed), will hold the actuator closed and the shutter in position, even after an actuation voltage is applied to the opposing actuator. The minimum voltage needed to maintain a shutter's position against such an opposing force is referred to as a maintenance voltage Vₘ.

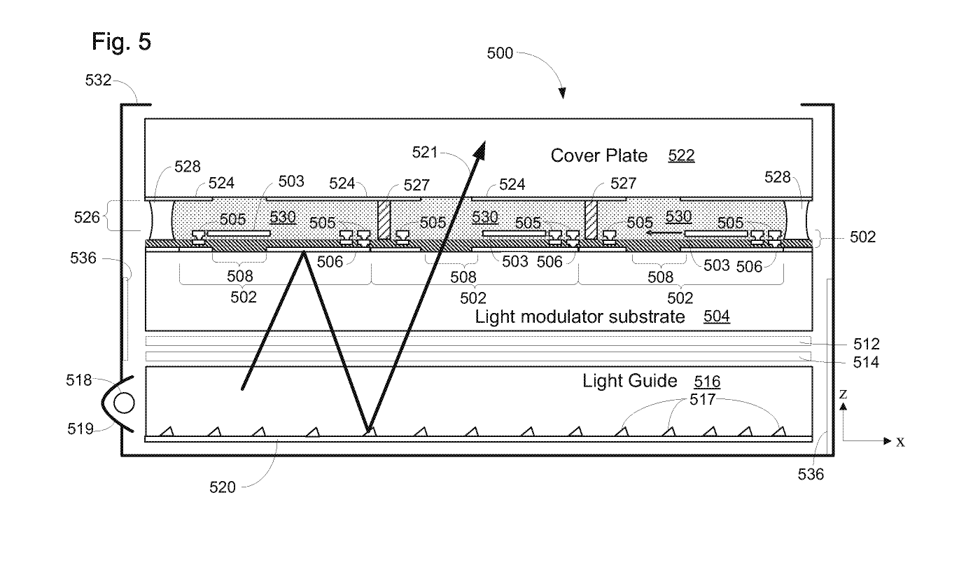

FIG. 5 is a cross sectional view of a display apparatus 500 incorporating shutter-based light modulators (shutter assemblies) 502. Each shutter assembly incorporates a shutter 503 and an anchor 505. Not shown are the compliant beam actuators which, when connected between the anchors 505 and the shutters 503, help to suspend the shutters a short distance above the surface. The shutter assemblies 502 are disposed on a transparent substrate 504, and may be made of plastic or glass. A rear-facing reflective layer, reflective film 506, disposed on the substrate 504 defines a plurality of surface apertures 508 located beneath the closed positions of the shutters 503 of the shutter assemblies 502. The reflective film 506 reflects light not passing through the surface apertures 508 back towards the rear of the display apparatus 500. The reflective aperture layer 506 can be a fine-grained metal film without inclusions formed in thin film fashion by a number of vapor deposition techniques including sputtering, evaporation, ion plating, laser ablation, or chemical vapor deposition. In another implementation, the rear-facing reflective layer 506 can be formed from a mirror, such as a dielectric mirror. A dielectric mirror is fabricated as a stack of dielectric thin films which alternate between materials of high and low refractive index. The vertical gap which separates the shutters 503 from the reflective film 506, within which the shutter is free to move, is in the range of 0.5 to 10 microns. The magnitude of the vertical gap may be less than the lateral overlap between the edge of shutters 503 and the edge of apertures 508 in the closed state, such as the overlap 416 shown in FIG. 4B.

The display apparatus 500 includes an optional diffuser 512, an optional brightness enhancing film 514, or combination thereof, which separates the substrate 504 from a planar light guide 516. The light guide includes a transparent, i.e. glass or plastic material. The light guide 516 is illuminated by one or more light sources 518, forming a backlight. The light sources 518 can be, for example, and without limitation, incandescent lamps, fluorescent lamps, lasers, or light emitting diodes (LEDs). A reflector 519 helps direct light from lamp 518 towards the light guide 516. A front-facing reflective film 520 is disposed behind the backlight 516, reflecting light towards the shutter assemblies 502. Light rays such as ray 521 from the backlight that do not pass through one of the shutter assemblies 502 will be returned to the backlight and reflected again from the film 520. In this fashion light that fails to leave the display to form an image on the first pass can be recycled and made available for transmission through other open apertures in the array of shutter assemblies 502. Such light recycling has been shown to increase the illumination efficiency of the display.

The light guide 516 includes a set of geometric light redirectors or prisms 517 which re-direct light from the lamps 518 towards the apertures 508 and hence toward the front of the display. The light re-directors can be molded into the plastic body of light guide 516 with shapes that can be alternately triangular, trapezoidal, or curved in cross section. The density of the prisms 517 generally increases with distance from the lamp 518.

In alternate implementations, the aperture layer 506 can be made of a light absorbing material, and in alternate implementations the surfaces of shutter 503 can be coated with either a light absorbing or a light reflecting material. In alternate implementations the aperture layer 506 can be deposited directly on the surface of the light guide 516. In alternate implementations the aperture layer 506 need not be disposed on the same substrate as the shutters 503 and anchors 505 (see the MEMS-down configuration described below).

In one implementation, the light sources 518 can include lamps of different colors, for instance, the colors red, green, and blue. A color image can be formed by sequentially illuminating images with lamps of different colors at a rate sufficient for the human brain to average the different colored images into a single multi-color image. The various color-specific images are formed using the array of shutter assemblies 502. In another implementation, the light source 518 includes lamps having more than three different colors. For example, the light source 518 may have red, green, blue and white lamps or red, green, blue, and yellow lamps.

A cover plate 522 forms the front of the display apparatus 500. The rear side of the cover plate 522 can be covered with a black matrix 524 to increase contrast. In alternate implementations the cover plate includes color filters, for instance distinct red, green, and blue filters corresponding to different ones of the shutter assemblies 502. The cover plate 522 is supported a predetermined distance away from the shutter assemblies 502 forming a gap 526. The gap 526 is maintained by mechanical supports, spacers 527, by an adhesive seal 528 attaching the cover plate 522 to the substrate 504, or any combination thereof.

The adhesive seal 528 seals in a working fluid 530. The working fluid 530 is engineered with viscosities that may be below about 10 centipoise and with relative dielectric constant that may be above about 2.0, and dielectric breakdown strengths above about 10⁴ V/cm. The working fluid 530 can also serve as a lubricant. In one implementation, the working fluid 530 is a hydrophobic liquid with a high surface wetting capability. In alternate implementations the working fluid 530 has a refractive index that is either greater than or less than that of the substrate 504.

When the MEMS-based display assembly includes a liquid for the working fluid 530, the liquid at least partially surrounds the moving parts of the MEMS-based light modulator. In order to reduce the actuation voltages, the liquid has a viscosity that may be below 70 centipoise, or even below 10 centipoise. Liquids with viscosities below 70 centipoise can include materials with low molecular weights: below 4000 grams/mole, or in some cases below 400 grams/mole. Suitable working fluids 530 include, without limitation, de-ionized water, methanol, ethanol and other alcohols, paraffins, olefins, ethers, silicone oils, fluorinated silicone oils, or other natural or synthetic solvents or lubricants. Useful working fluids can be polydimethylsiloxanes, such as hexamethyldisiloxane and octamethyltrisiloxane, or alkyl methyl siloxanes such as hexylpentamethyldisiloxane. Useful working fluids can be alkanes, such as octane or decane. Useful fluids can be nitroalkanes, such as nitromethane. Useful fluids can be aromatic compounds, such as toluene or diethylbenzene. Useful fluids can be ketones, such as butanone or methyl isobutyl ketone. Useful fluids can be chlorocarbons, such as chlorobenzene. Useful fluids can be chlorofluorocarbons, such as dichlorofluoroethane or chlorotrifluoroethylene. And other fluids considered for these display assemblies include butyl acetate, dimethylformamide.

For many implementations, it is advantageous to incorporate a mixture of the above fluids. For instance mixtures of alkanes or mixtures of polydimethylsiloxanes can be useful where the mixture includes molecules with a range of molecular weights. It is also possible to optimize properties by mixing fluids from different families or fluids with different properties. For instance, the surface wetting properties of a hexamethyldisiloxane and be combined with the low viscosity of butanone to create an improved fluid.

A sheet metal or molded plastic assembly bracket 532 holds the cover plate 522, the substrate 504, the backlight 516 and the other component parts together around the edges. The assembly bracket 532 is fastened with screws or indent tabs to add rigidity to the combined display apparatus 500. In some implementations, the light source 518 is molded in place by an epoxy potting compound. Reflectors 536 help return light escaping from the edges of light guide 516 back into the light guide. Not shown in FIG. 5 are electrical interconnects which provide control signals as well as power to the shutter assemblies 502 and the lamps 518.

Display apparatus 500 is referred to as the MEMS-up configuration, where the MEMS based light modulators are formed on a front surface of substrate 504, i.e. the surface that faces toward the viewer. The shutter assemblies 502 are built directly on top of the reflective aperture layer 506. In an alternate implementation, referred to as the MEMS-down configuration, the shutter assemblies are disposed on a substrate separate from the substrate on which the reflective aperture layer is formed. The substrate on which the reflective aperture layer is formed, defining a plurality of apertures, is referred to herein as the aperture plate. In the MEMS-down configuration, the substrate that carries the MEMS-based light modulators takes the place of the cover plate 522 in display apparatus 500 and is oriented such that the MEMS-based light modulators are positioned on the rear surface of the top substrate, i.e. the surface that faces away from the viewer and toward the back light 516. The MEMS-based light modulators are thereby positioned directly opposite to and across a gap from the reflective aperture layer. The gap can be maintained by a series of spacer posts connecting the aperture plate and the substrate on which the MEMS modulators are formed. In some implementations, the spacers are disposed within or between each pixel in the array. The gap or distance that separates the MEMS light modulators from their corresponding apertures may be less than 10 microns, or a distance that is less than the overlap between shutters and apertures, such as overlap 416.

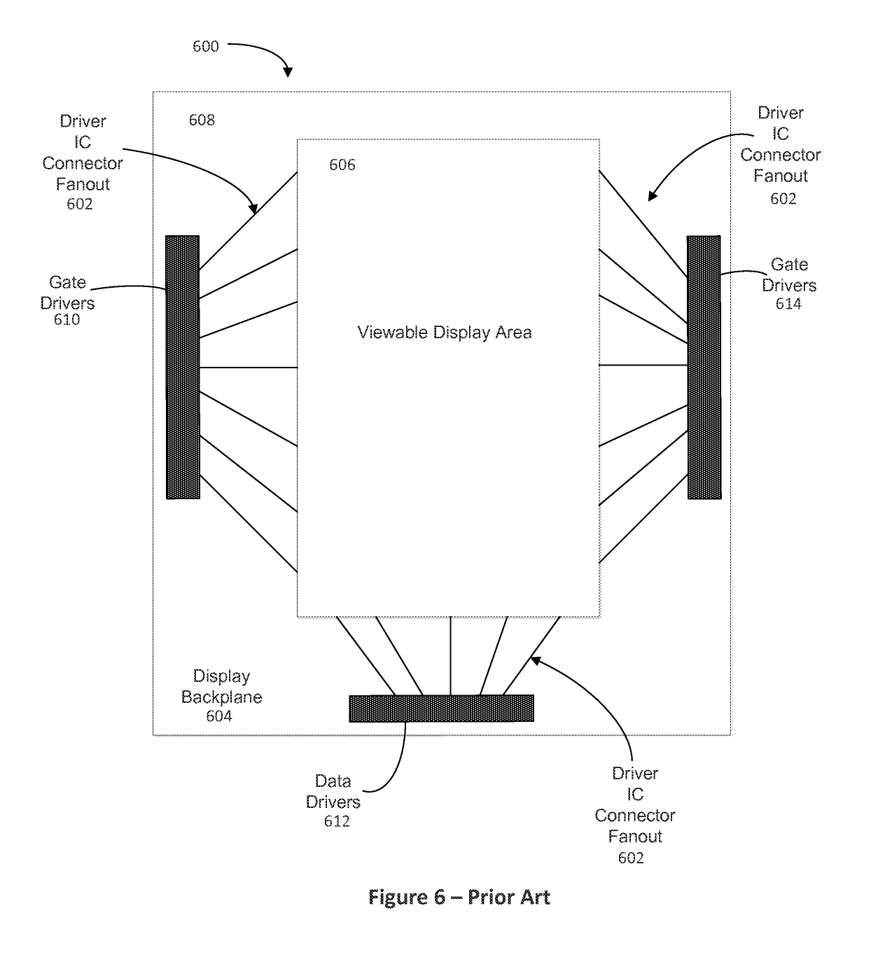

FIG. 6 is a diagram of a prior art display 600 illustrating interconnect wire fan out 602 from the silicon-based IC driver chips 610, 612, and 614 that are bonded to display backplane 604. The display includes a backplane 604 which is typically a glass substrate including a viewable portion or area 606 and non-viewable portion or area 608. Each COG driver chip 610, 612, and 614 is located on the non-viewable portion 608. Each connector fan out 602 includes multiple electronically conductive routing lines or interconnect wires that carry electrical signals from each silicon driver chip 610, 612, and 614 to each row and column of an array of light modulators located in the viewable display area 606.

The silicon chips used as driver chips 610, 612, and 614 are relatively small because as the size of a silicon chip increases, the chip becomes more susceptible to fracturing or cracking Because the silicon driver chips 610, 612, and 614 are relatively small, the silicon driver chips 610, 612, and 614 require a sufficient fan-out 602 of their interconnect wires from each chip to connect to each of the rows or columns of the array of pixels in the viewable display area 606 of display 600. Unfortunately, this increases the shelf or bezel area of the display 600 which reduces the viewable display area 606.

Additionally, there is a coefficient of thermal expansion (CTE) mismatch between the silicon driver chips 610, 612, and 614 with the glass of the display backplane 608 which makes bonding larger chips difficult and potentially unreliable. For example, the mismatch in expansion could break the bond between a silicon driver chip 610, 612, or 614 and the glass display backplane 608, or even damage the driver chip 610, 612, or 614. Bonding of a driver chip 610, 612, or 614 to the display backplane 608 is typically performed using thermal compression bonding or anisotropic conductive film (ACF) bonding.

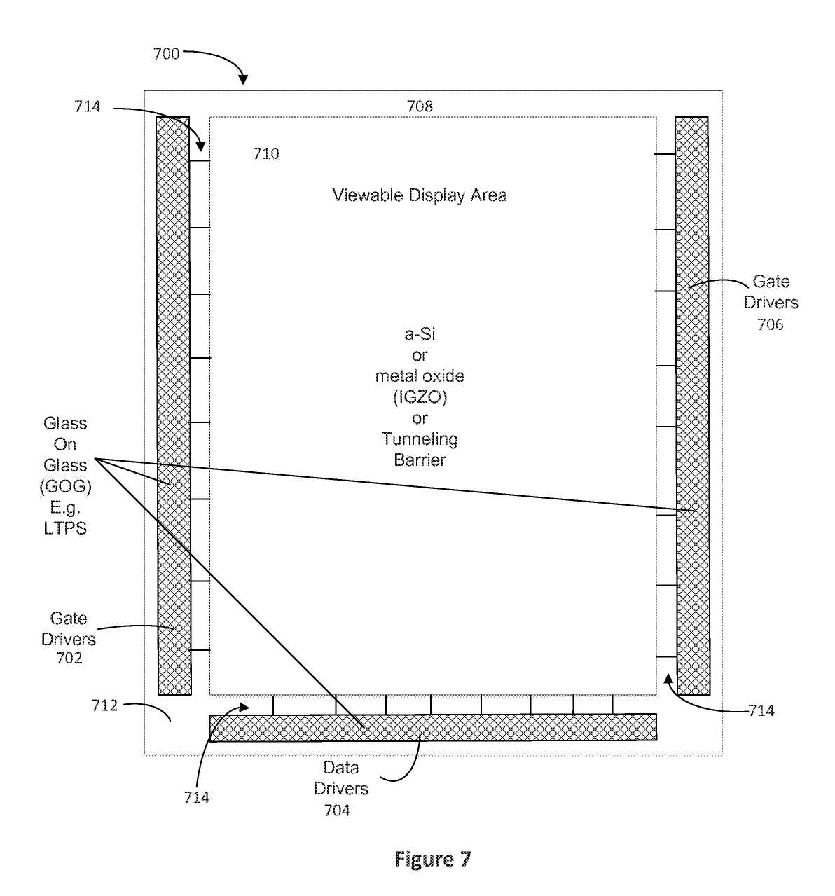

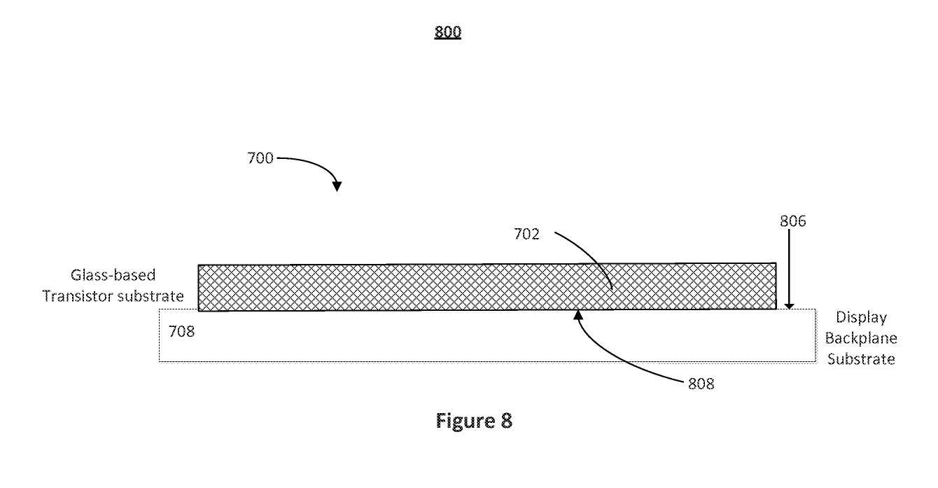

FIG. 7 is a diagram of a display 700 including glass-based driver chips 702, 704, and 706. The display includes a backplane 708 which may include a glass substrate. The display backplane 708 may have a control matrix in a viewable display area 710, such as control matrix 300 of FIG. 3, arranged on a surface of the display backplane 708, such as surface 806 of FIG. 8. Each driver chip 702, 704, and 706 may be positioned or located on the non-viewable portion 712. The driver chips 702, 704, and 706 may be connected to electromechanical devices in the viewable display area 710 via routing lines 714. The driver chips 702, 704, and 706 may include integrated circuits fabricated upon glass substrates. In other implementations, the integrated circuits can be formed upon substrates other than glass that also have CTEs that are similar or the same as the underlying display backplane substrate, which may be formed of glass or other materials. Such IC chip substrates should also allow for fabrication processes that allow the chip contact pads to be spaced apart sufficiently such that upon chip attachment to the display backplane, interconnect wire fan out is minimized.

The display 700 may include a plurality of light modulators, such as the array 320 of light modulators shown in FIG. 3. The control matrix 300 may also include at least a metal oxide transistor, an amorphous silicon (a-Si) transistor, or tunneling barrier device, acting as a driver transistor in the viewable portion 710, to drive at least one light modulator of the array 320.

FIG. 8 is a side view 800 of the display 700 illustrating a glass-based IC chip 702 bonded to a display backplane or substrate 708. In one configuration, integrated circuits are formed on the glass substrate 702 which is different than the substrate used for the display backplane 708. The chip 702 may be connectable to the substrate of the display backplane 708. The chip 702 (e.g., second substrate) may be bonded to the substrate of the display backplane 708 (e.g., first substrate). The chip 702 may be permanently bonded to the display backplane 708. In some implementations, chip 702 is tested before bonding to the display backplane 708. The bonding process may include at least one of anodic bonding, fusion, thermal compression bonding, anisotropic conductive film (ACF) bonding, or applying an adhesive between the first and second substrates. The adhesive may include, without limitation, an epoxy adhesive such as commonly used for sealing liquid crystal cells.

In certain configurations, a glass-based IC chip includes circuits formed of LTPS. In some implementations, the first portion, region, or area 712 is located substantially along a periphery of the display backplane 712. Each glass-based IC chip may function as a gate driver or data driver. The chip 702 may also include at least one contact pad for connection with a corresponding interconnect wire or routing line on the display backplane 708, which then leads to and connects to at least one row or column electrode of the display 700. In some configurations, all or a substantial portion of the surface 806 of substrate 708 is bonded to, connected to, or arranged in contact with all or a substantial portion of the surface 808 of chip 702.

Because the IC chips are arranged and/or formed on glass, instead of silicon, there is little to no CTE mismatch between the glass-based transistor chips 702, 704, and 706 and the display backplane 708 as opposed to the mismatch experienced using silicon chips on glass substrates. Also, contact or bond pads on the glass chip 702, 704, or 706 may be relatively large in size to relax the alignment tolerance between, for example, the driver chip 702 and the rows of an array 320 of light modulators in the viewable display area 710.

Furthermore, a relatively large glass-based IC chip such as chip 702, 704, or 706, has contact pads with a larger pitch (distance between each contact pad) as compared to a silicon chip, which allows for each chip contact pad to be more aligned with a corresponding row or column electrode. As such, routing lines leading from the IC chip do not need to spread outwards or fan out towards corresponding row or column electrodes as much or at all compared to when smaller silicon IC chips are used. Therefore, a glass-based chip 702, 704, or 706 requires less surface area of the backplane substrate for routing lines to spread out and therefore is able to have a slimmer border or non-viewable area 712 on the display backplane 708 as opposed to the wider border or non-viewable area 608 required for silicon IC chip fan-out 602 as shown in FIG. 6. One advantage of the slimmer border profile is that a larger portion of the display backplane 708 can be used as the viewable displayable area 710.

Another advantage of using glass-based chips 702, 704, and 706 is that the glass-based chips 702, 704, and 706 can be formed on a glass substrate separately from the display backplane 708 and then bonded to the edges or periphery of the display backplane 708. Such a process enables the glass-based driver chips 702, 704, and 706 to be tested for proper operation prior to their addition to the display backplane 708. This reduces the overall cost of manufacturing displays by requiring only replacement of faulty glass-based driver chips 702, 704, and 706 instead of the whole display 700. Also, by forming a glass-based driver chip 702, 704, or 706 on a separate substrate (e.g., glass), the relatively more expensive LTPS process can be limited to the glass-based driver chip, while less expensive TFT technology (e.g., A-Si, IGZO, or tunneling barrier devices) are used as switches for the pixels of the array 320 in the viewable display area 710.

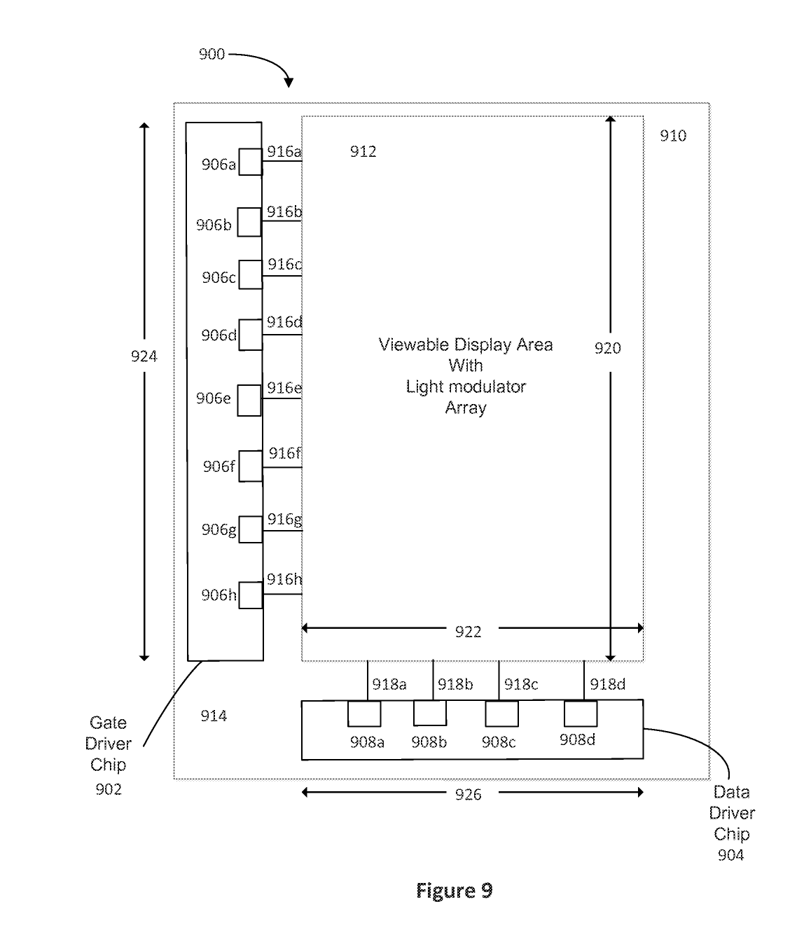

FIG. 9 is another diagram of a display 900 illustrating the alignment of the contact or bond pads 906a-h on a glass-based driver chip 902 with the rows of a light modulator array, such as array 320 within display area 912, and the alignment of the contact or bond pads 908a-d on a glass-based driver chip 904 with the columns of a light modulator array, such as array 320 within display area 912. The display includes a backplane 910 which may include a glass substrate. The display backplane 910 may have a control matrix, such as control matrix 300 of FIG. 3, arranged on a surface of the display backplane 910. Each driver chip 902 and 904 may be positioned or located about the periphery of the light modulator array 912. The driver chips 902 and 904 include integrated circuits fabricated upon glass substrates.

As discussed above, the contact or bond pads 906 or 908 on the glass chip 902 or 904 respectively may be relatively large as compared to a silicon chip to relax the alignment tolerance between the driver transistors and the rows (or columns) of the array 320 in the viewable display area 912. Furthermore, a relatively large glass-based IC chip 902 or 904, as compared to a silicon chip, requires substantially less fan-out. Therefore, a glass-based IC chip 902 or 904 is able to maintain a slimmer border or non-viewable area 914 on the display backplane 910 as opposed to the wider border required for silicon IC chip fan-out.

In some configurations, each contact pad 906 of driver chip 902 is substantially aligned with a corresponding row of an array 320 of light modulators via routing lines 916. Similarly, each connector 908 of data driver chip 904 may be substantially aligned with a corresponding column of the array 320 of light modulators via interconnect wires 918. The length 924 of driver chip 902 may be approximately equal to a length 920 of the viewable display area 912 or the length of a column of the array 320. The length 926 of the data driver chip 904 may be approximately equal to a width 922 of the viewable display area 912 or the length of a row of the array 320. Hence, in some configurations, a plurality of electromechanical devices within the display area 912 can extend along a first length, e.g., length 920, and the IC chip 902 can have an edge of an IC chip length 924 such that the edge of the IC chip 902 is adjacent to and aligned with the length 920 of the electromechanical devices, whereby the length 920 is substantially equal to IC chip length 924.

In another configuration, the length of the gate driver chip 902 may be less than the length 920 of the viewable display area 912 or the length of the rows of the array 320, but sufficient to reduce the fan out of the routing lines 916. The length of the driver chip 904 may also be less than the width 922 of the viewable display area 912 or the length of the columns of the array 320, but sufficient to reduce the fan out of the interconnect wires 918. In a further configuration, instead of a single IC chip 902 being aligned along the length 920, two or more IC chips can be aligned adjacent to a plurality of electromechanical devices within the display area 912 such that each of the routing lines 916 is substantially aligned with at least one contact pad of the two or more IC chips. In yet another configuration, each of the two or more IC chips may function as a gate or data driver for a portion or section of electromechanical devices within the display area 912. One advantage of such a configuration is that multiple portions or sections of the electromechanical devices of the display 900 may be driven concurrently.

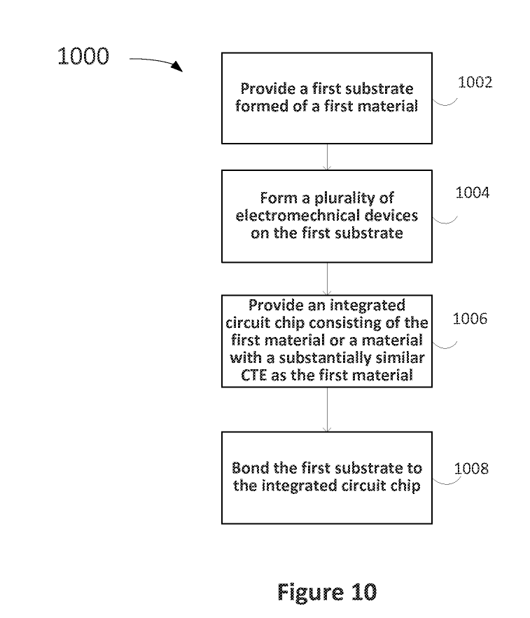

FIG. 10 is a flow diagram of a process 1000 for manufacturing a device, such as, for example, display 700 or 900, including an integrated circuit chip. The process 1000 includes providing a first substrate formed of a first material, such as display backplane 708 or 910 (Block 1002). Then, forming a plurality of electromechanical devices, e.g., light modulators, such as in array 320 on the first substrate (Block 1004). Then, providing an integrated circuit chip, e.g. chip 702, 704, 706, 902, or 904 (Block 1006). Finally, bonding the first substrate to the integrated circuit chip (Block 1008).

In certain implementations, the process 1000 includes forming the IC chip, such as IC chip 902 by fabricating an active thin film circuit and a contact pad 906 on a glass substrate such as, for example, backplane 910. The process 1000 may further include forming a plurality of routing lines, such as routing lines 916 or 918, in the first substrate 910 such that they extend away from the plurality of electromechanical devices, which may be formed in within a viewable display area 912. The IC chip 902 or 904 may also have a plurality of contact pads, e.g., contact pads 906a-h or 908a-d respectively, such that the process 1000 includes extending each of the routing lines 916a-h or 918a-d towards and connecting each of the routing lines 916a-h or 918a-d with a respective contact pad 906a-h or 908a-d. The process 1000 may include extending each of the routing lines 916a-h or 918a-d along a straight line from the electromechanical devices towards the IC chip 902 or 904 respectively. The process 1000 may include connecting each of the routing lines 916a-h or 918a-d to the IC chip 902 or 904 respectively at substantially a perpendicular angle with an edge of the IC chip 902 or 904. The process 1000 may further include aligning each contact pad 906a-h or 908a-d substantially with at least one corresponding row and one corresponding column of pixels of a display 900.

The bonding process may include any one or combination of anodic bonding, fusion, thermal compression bonding, anisotropic conductive film (ACF) bonding, or applying an adhesive between the first and second substrates. The method may also include forming a plurality of glass-based transistors on the IC chip 902 or 904 where each glass based transistor includes at least one contact pad 906 or 908. The method may further include aligning each of the at least one contact pad 906 or 908 with a corresponding routing line of a light modulator on the first substrate 910. The IC chip 902 or 904 may be bonded to a periphery of the first substrate 910.

In one implementation, the first substrate 910 is bonded to a second substrate 902 or 904 via an adhesive such as, without limitation, an epoxy adhesive such as commonly used for sealing liquid crystal cells.

In another implementation, first substrate and IC chip are bonded using bonding techniques known to a person of ordinary skill to facilitate bonding of a glass-based transistor substrate to a display backplane.

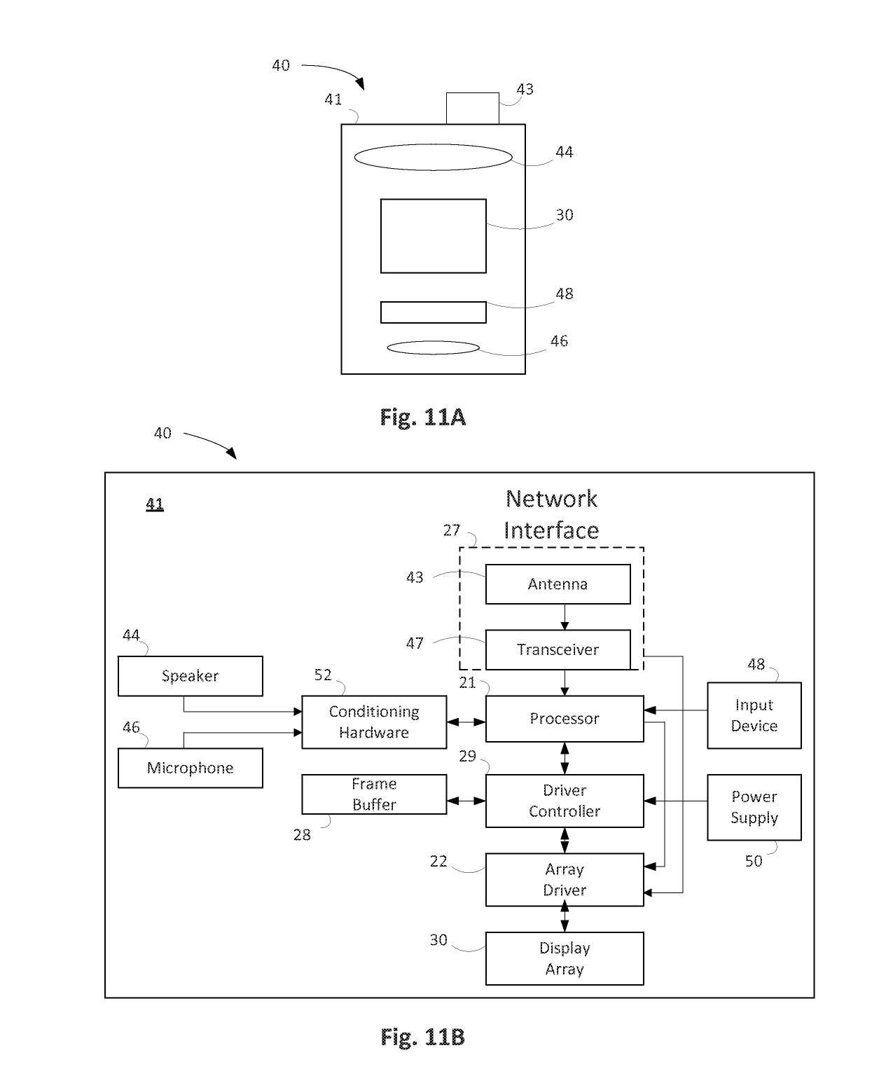

FIGS. 11A and 11B are system block diagrams illustrating a display device 40 that includes a plurality of light modulator display elements. The light modulator display elements may include one or more glass-based transistors or chips such as described with respect to FIGS. 7-10 herein. The display device 40 can be, for example, a smart phone, a cellular or mobile telephone. However, the same components of the display device 40 or slight variations thereof are also illustrative of various types of display devices such as televisions, computers, tablets, e-readers, hand-held devices and portable media devices.

The display device 40 includes a housing 41, a display 30, an antenna 43, a speaker 45, an input device 48 and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an light modulator-based display, as described herein.

The components of the display device 40 are schematically illustrated in FIG. 11A. The display device 40 includes a housing 41 and can include additional components at least partially enclosed therein. For example, the display device 40 includes a network interface 27 that includes an antenna 43 which can be coupled to a transceiver 47. The network interface 27 may be a source for image data that could be displayed on the display device 40. Accordingly, the network interface 27 is one example of an image source module, but the processor 21 and the input device 48 also may serve as an image source module. The transceiver 47 is connected to a processor 21, which is connected to conditioning hardware 52. The conditioning hardware 52 may be configured to condition a signal (such as filter or otherwise manipulate a signal). The conditioning hardware 52 can be connected to a speaker 45 and a microphone 46. The processor 21 also can be connected to an input device 48 and a driver controller 29. The driver controller 29 can be coupled to a frame buffer 28, and to an array driver 22, which in turn can be coupled to a display array 30. One or more elements in the display device 40, including elements not specifically depicted in FIG. 11A, can be configured to function as a memory device and be configured to communicate with the processor 21. In some implementations, a power supply 50 can provide power to substantially all components in the particular display device 40 design.

The network interface 27 includes the antenna 43 and the transceiver 47 so that the display device 40 can communicate with one or more devices over a network. The network interface 27 also may have some processing capabilities to relieve, for example, data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g, n, and further implementations thereof. In some other implementations, the antenna 43 transmits and receives RF signals according to the Bluetooth® standard. In the case of a cellular telephone, the antenna 43 can be designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1×EV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G, 4G or 5G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, in some implementations, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that can be readily processed into raw image data. The processor 21 can send the processed data to the driver controller 29 or to the frame buffer 28 for storage. Raw data typically refers to information that identifies the image characteristics at each location within an image. For example, such image characteristics can include color, saturation and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29, which may include one or more glass-based transistors, can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22, which may include one or more glass-based transistors as described in FIGS. 7-10, can receive the formatted information from the driver controller 29 and can re-format the video data into a parallel set of waveforms that are applied many times per second to the hundreds, and sometimes thousands (or more), of leads coming from the display's x-y matrix of display elements.

In some implementations, the driver controller 29, the array driver 22, and the display array 30 are appropriate for any of the types of displays described herein. For example, the driver controller 29 can be a conventional display controller or a bi-stable display controller (such as a light modulator display element controller). Additionally, the array driver 22 can be a conventional driver or a bi-stable display driver (such as a light modulator display element driver). Moreover, the display array 30 can be a conventional display array or a bi-stable display array (such as a display including an array of light modulator display elements). In some implementations, the driver controller 29 can be integrated with the array driver 22. Such an implementation can be useful in highly integrated systems, for example, mobile phones, portable-electronic devices, watches or small-area displays.

In some implementations, the input device 48 can be configured to allow, for example, a user to control the operation of the display device 40. The input device 48 can include a keypad, such as a QWERTY keyboard or a telephone keypad, a button, a switch, a rocker, a touch-sensitive screen, a touch-sensitive screen integrated with the display array 30, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices. For example, the power supply 50 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware components, software components, or combination thereof, and in various configurations.

Variations and modifications can be made to the implementations described above without substantially departing from the principles of the present application. Such variations and modifications are also intended to be included within the scope of the appended claims. Therefore, the forgoing implementations are to be considered in all respects illustrative, rather than limiting of the application.

What is claimed is:

1. A device comprising:
a first substrate formed of a first material;
a plurality of electromechanical devices formed upon a surface of the first substrate;
an integrated circuit (IC) chip bonded to the surface of the first substrate, the integrated circuit chip formed of a material selected from a group consisting of the first material or a material having a coefficient of thermal expansion (CTE) that is substantially similar to the CTE of the first material.

2. The device of claim 1, wherein the first substrate is substantially transparent.

3. The device of claim 2, wherein the IC chip is substantially transparent.

4. The device of claim 1, wherein the integrated circuit chip includes a glass-based IC chip.

5. The device of claim 4, wherein the first substrate is formed of glass.

6. The device of claim 5, wherein the IC chip includes a low temperature polysilicon (LTPS) transistor.

7. The device of claim 1, wherein the first substrate includes a display backplane.

8. The device of claim 7, wherein the IC chip is located substantially along a periphery of the display backplane.

9. The device of claim 1, wherein the IC chip functions as at least one of a gate driver and data driver.

10. The device of claim 1, further comprising a plurality of routing lines formed in the first substrate such that they extend away from the plurality of electromechanical devices and wherein the IC chip has a plurality of contact pads, and wherein each of the routing lines extends towards and connects with a respective contact pad.

11. The device of claim 10, wherein each of the routing lines extends along a straight line from the electromechanical devices towards the integrated circuit chip.

12. The device of claim 11, wherein each of the routing lines connect to the integrated circuit chip at substantially a perpendicular angle with an edge of the integrated circuit chip.

13. The device of claim 10, wherein the each contact pad is substantially aligned with at least one corresponding row and one corresponding column of pixels of a display.

14. The device of claim 10, wherein the plurality of electromechanical devices extend along a first length and the IC chip has an edge of a second length, wherein the edge of the IC chip is adjacent to and aligned with the first length of the electromechanical devices, and the first length is substantially equal to second length.

15. The device of claim 1, further comprising a control matrix being arranged to communicate with the IC chip and a processor being arranged to communicate with the IC chip, the processor being configured to process image data and communicate with a memory device.

16. The device of claim 15, wherein the IC chip is configured to receive at least a portion of the image data from a controller.

17. The device of claim 16, wherein the processor is configured to receive the image data from an image source module, the image source module including at least one of a receiver, transceiver, and transmitter.

18. A glass-based chip comprising:
a first glass substrate being connectable with a display backplane; and
a transistor being formed on the first glass substrate and arranged to drive at least one light modulator on the display backplane after the first substrate is connected to the display backplane.

19. The glass-based chip of claim 18, wherein the transistor is formed of low temperature polysilicon (LTPS).

20. The glass-based chip of claim 18, further comprising a plurality of glass-based transistors and comprising at least one contact pad being associated with each of the plurality of glass-based transistors that connects with a corresponding routing drive line of a light modulator on the display backplane.

21. The glass-based chip of claim 20, wherein each contact pad is substantially aligned with at least one corresponding row and one corresponding column of pixels on the display backplane.

22. A method for manufacturing a device comprising:
providing a first substrate formed of a first material;
forming a plurality of electromechanical devices on the first substrate;
providing an integrated circuit (IC) chip, the integrated circuit chip being formed of a material selected from a group consisting of the first material or a material having a coefficient of thermal expansion (CTE) that is substantially similar to the CTE of the first material; and
bonding the integrated circuit chip to the first substrate.

23. The method of claim 22, comprising forming the IC chip by fabricating an active thin film circuit and a contact pad on a glass substrate.

24. The method of claim 22, wherein the first material is glass.

25. The method of claim 22, further comprising forming a plurality of routing lines in the first substrate such that they extend away from the plurality of electromechanical devices and wherein the IC chip has a plurality of contact pads, and comprising extending each of the routing lines towards and connecting each of the routing lines with a respective contact pad.

26. The method of claim 25, further comprising extending each of the routing lines along a straight line from the electromechanical devices towards the IC chip.

27. The method of claim 26, further comprising connecting each of the routing lines to the IC chip at substantially a perpendicular angle with an edge of the IC chip.

28. The method of claim 25, further comprising aligning each contact pad substantially with at least one corresponding row and one corresponding column of pixels of a display.

29. The device of claim 25, wherein the plurality of electromechanical devices extend along a first length and the IC chip has an edge of a second length, wherein the edge of the IC chip is adjacent to and aligned with the first length of the electromechanical devices, and the first length is substantially equal to second length.

30. The method of claim 22, further comprising forming at least one glass-based transistor on the IC chip.

31. The method of claim 30, further comprising testing the at least one glass-based transistor before bonding the IC chip to the first substrate.
